(19) United States
(12) Patent Application Publication
(10) Pub. No.: US 2026/0165077 A1
(43) Pub. Date: Jun. 11, 2026

(54) SUBSTRATE PROCESSING METHOD AND SUBSTRATE PROCESSING APPARATUS

(71) Applicant: Tokyo Electron Limited, Tokyo (JP)

(72) Inventors: Akira FUJITA, Kumamoto (JP); Kazuhiro AIURA, Kumamoto (JP); Yoshifumi AMANO, Kumamoto (JP); Tatsuhiko TSUJIHASHI, Kumamoto (JP)

(73) Assignee: Tokyo Electron Limited, Tokyo (JP)

(21) Appl. No.: 18/706,088

(22) PCT Filed: Oct. 21, 2022
(86) PCT No.: PCT/JP2022/039206

§ 371 Date: Apr. 30, 2024

(30) Foreign Application Priority Data
Nov. 4, 2021 (JP) 2021-180411

(51) Int. Cl. H10P 72/00; G01B 21/32; G01J 5/00; G01J 5/08; G01J 5/48; H10P 70/00

(52) U.S. Cl. CPC H10P 72/0602; G01B 21/32; G01J 5/0859; G01J 5/485; H10P 70/54; H10P 72/0414; H10P 72/0616; G01J 2005/0077

(57) ABSTRACT

A substrate processing method includes holding a substrate by using a holding part that holds the substrate horizontally and rotatably, subsequently heating the substrate that is held thereby, subsequently regulating a temperature of a peripheral part of the substrate that rotates before a first processing liquid is discharged from a first nozzle that is arranged at a predetermined processing position to the peripheral part, in such a manner that an in-plane temperature distribution of the substrate approaches an in-plane temperature distribution during discharging of the first processing liquid from the first nozzle that is arranged at the processing position to the peripheral part of the substrate that rotates, and subsequently discharging the first processing liquid from the first nozzle that is arranged at the processing position to the peripheral part of the substrate that rotates.

### FIELD

The present disclosure relates to a substrate processing method and a substrate processing apparatus.

### BACKGROUND

A technique has conventionally been known that Supplies a processing liquid to a peripheral part of a substrate such as a silicon wafer and/or a compound semiconductor wafer so as to etch and remove a film that is formed on such a peripheral part of a substrate (see Patent Literature 1).

### CITATION LIST

### Patent Literature

Patent Literature 1: Japanese Patent No. 6815799

### SUMMARY

### Technical Problem

The present disclosure provides a technique is capable of reducing or preventing varying of a removal width of a film on a peripheral part of a substrate between substrates that is caused by warpage of such a substrate that is temporarily caused during processing of such a substrate.

### Solution to Problem

A substrate processing method according to an aspect of the present disclosure includes holding a substrate by using a holding part that holds the substrate horizontally and rotatably, subsequently heating the substrate that is held thereby, subsequently regulating a temperature of a peripheral part of the substrate that rotates before a first processing liquid is discharged from a first nozzle that is arranged at a predetermined processing position to the peripheral part, in such a manner that an in-plane temperature distribution of the substrate approaches an in-plane temperature distribution during discharging of the first processing liquid from the first nozzle that is arranged at the processing position to the peripheral part of the substrate that rotates, and subsequently discharging the first processing liquid from the first nozzle that is arranged at the processing position to the peripheral part of the substrate that rotates.

### Advantageous Effects of Invention

According to the present disclosure, it is possible to reduce or prevent varying of a removal width of a film on a peripheral part of a substrate between substrates that is caused by warpage of such a substrate that is temporarily caused during processing of such a substrate.

### BRIEF DESCRIPTION OF DRAWINGS

FIG. 1 is a diagram that illustrates a general configuration of a substrate processing system according to an embodiment.

FIG. 2 is a schematic plan view that illustrates a configuration of a processing unit according to an embodiment.

FIG. 3 is a schematic cross-sectional view that illustrates a configuration of a processing unit according to an embodiment.

FIG. 4 is a flowchart that illustrates a series of processing procedures that is executed by a processing unit according to an embodiment.

FIG. 5 is a timing chart that illustrates an example of an operation of each part in a temperature regulation process according to an embodiment.

FIG. 6 is a diagram that illustrates an example of an operation of a chemical liquid nozzle and a back surface nozzle in a temperature regulation process according to an embodiment.

FIG. 7 is a diagram that illustrates an example of an operation of a chemical liquid nozzle and a back surface nozzle in a temperature regulation process according to an embodiment.

FIG. 8 is a timing chart that illustrates another example of an operation of each part in a temperature regulation process according to an embodiment.

FIG. 9 is a timing chart that illustrates another example of an operation of each part in a temperature regulation process according to an embodiment.

FIG. 10 is a schematic diagram that illustrates a configuration of a processing unit according to another embodiment.

FIG. 11 is a flowchart that illustrates a procedure of a recipe selection process that is executed by a processing unit according to another embodiment.

### DESCRIPTION OF EMBODIMENTS

Hereinafter, a mode(s) (that will be described as “an embodiment(s) ” below) for implementing a substrate processing method and a substrate processing apparatus according to the present disclosure will be explained in detail with reference to the drawing(s). Additionally, a substrate processing method and a substrate processing apparatus according to the present disclosure are not limited by such an embodiment(s). Furthermore, it is possible to combine respective embodiments appropriately as long as process contents thereof are not inconsistent. Furthermore, in each/respective under-mentioned embodiment(s), identical sites thereof will be provided with identical signs so as to omit a redundant explanation(s) thereof.

Furthermore, in each drawing as being referred to below, an orthogonal coordinate system where a direction(s) of an X-axis, a direction(s) of a Y-axis, and a direction(s) of a Z-axis that are orthogonal to one another are defined and a positive direction of such a Z-axis is provided as a vertically upward direction may be illustrated for sake of clarity of an explanation(s). Furthermore, a direction of rotation where a vertical axis is provided as a center of rotation may be called a θ-direction.

An edge cut process has been known that etches and removes a film that is formed on a peripheral part of a substrate with a processing liquid. An edge cut process may be executed while a substrate is heated in order to increase an etching rate.

Herein, as a peripheral part of a heated substrate is supplied with a processing liquid at a temperature (for example, an ordinary temperature) that is lower than that of such a substrate, a temperature of a peripheral part of such a substrate is lowered. Thereby, a temperature difference is caused between a peripheral part of a substrate and its area other than it (for example, a central part of such a substrate). Such a temperature difference causes warpage of a substrate. Hereinafter, warpage of a substrate that is caused by a temperature difference between a peripheral part of such a substrate and its area other than it will be described as “thermal warpage”.

Thermal warpage is temporary warpage that is caused on a substrate and is eliminated as an edge cut process is ended, that is, a temperature difference between a peripheral part of such a substrate and its area other than it is eliminated. Additionally, thermal warpage is caused by a temperature difference between a peripheral part of a substrate and its area other than it that is caused during an edge cut process. Hence, it goes without saying that thermal warpage is not present on a substrate before an edge cut process even if such a substrate has original warpage thereof.

Thermal warpage is gradually developed immediately after a processing liquid is supplied to a peripheral part of a substrate. Then, development of thermal warpage is stopped (thermal warpage is completed) as a certain amount of time passes after supply of a processing liquid is started. Additionally, although a period of time until thermal warpage is completed is different depending on a process condition(s) of an edge cut process (a heating temperature, a flow rate of a processing liquid, a position of discharging of a processing liquid, a liquid type of a processing liquid, a type of a substrate, a type of a film, etc.), it is substantially constant if such a condition(s) is/are identical.

In an edge cut process, while a processing liquid is discharged from a nozzle, such a nozzle is introduced from an outer side of a substrate to an upper side of such a substrate, so that such a processing liquid lands on a peripheral part of such a substrate at a preset target liquid landing point. A target liquid landing point is defined by a distance from an end surface of a substrate such as, for example, “1 mm from an end surface of a substrate”. A removal width (that will be described as a “cut width” below) of a film on a peripheral part of a substrate is defined by a target liquid landing point.

Herein, a position on a substrate that is set as a target liquid landing point varies due to development of thermal warpage thereof. Hence, in a case where a processing liquid lands at a target liquid landing position during developing of thermal warpage, that is, during varying of a position on a substrate that is set as such a target liquid landing point, a variation of a cut width thereof between substrates may be caused.

Hence, a technique that is capable of etching a peripheral part of a substrate accurately, specifically, a technique that is capable of reducing or preventing varying of a cut width of a peripheral part of a substrate between substrates that is caused by thermal warpage of such a substrate that is temporarily caused during processing of such a substrate, has been expected.

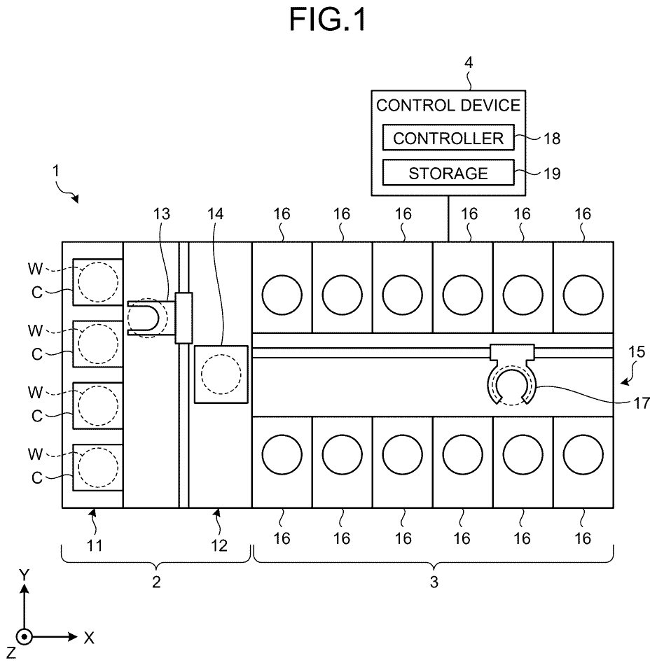

FIG. 1 is a diagram that illustrates a general configuration of a substrate processing system according to an embodiment. As illustrated in FIG. 1, a substrate processing system 1 includes a carry-in/out station 2 and a processing station 3. The carry-in/out station 2 and the processing station 3 are provided adjacently.

The carry-in/out station 2 includes a carrier placing section 11 and a transfer section 12. A plurality of carriers C that house a plurality of substrates, in an embodiment, semiconductor wafers (wafers W below), in a horizontal state thereof are placed on the carrier placing section 11.

The transfer section 12 is provided so as to be adjacent to the carrier placing section 11 and includes a substrate transfer device 13 and a delivery unit 14 in an inside thereof. The substrate transfer device 13 includes a wafer holding mechanism that holds a wafer W. Furthermore, the substrate transfer device 13 is capable of moving in a horizontal direction and a vertical direction and turning around a vertical axis that is provided as a center thereof, and executes transfer of a wafer W between a carrier C and the delivery unit 14 by using a wafer holding mechanism.

The processing station 3 is provided so as to be adjacent to the transfer section 12. The processing station 3 includes a transfer section 15 and a plurality of processing units 16 (examples of a substrate processing device). The plurality of processing units 16 are provided side by side at both sides of the transfer section 15. Additionally, a number of a processing unit(s) 16 that is/are included in the substrate processing system 1 is not limited to that of an illustrated example.

The transfer section 15 includes a substrate transfer device 17 in an inside thereof. The substrate transfer device 17 includes a wafer holding mechanism that holds a wafer W. Furthermore, the substrate transfer device 17 is capable of moving in a horizontal direction and a vertical direction and turning around a vertical axis that is provided as a center thereof, and executes transfer of a wafer W between the delivery unit 14 and a processing unit 16 by using a wafer holding mechanism.

A processing unit 16 executes predetermined substrate processing for a wafer W that is transferred by the substrate transfer device 17.

Furthermore, the substrate processing system 1 includes a control device 4. The control device 4 is, for example, a computer, and includes a controller 18 and a storage 19. The storage 19 is realized by, for example, a semiconductor memory element such as a RAM or a flash memory (Flash Memory) or a storage device such as a hard disk or an optical disk, and stores a program that controls various types of processes that are executed in a processing unit 16. The controller 18 includes a microcomputer that has a CPU (Central Processing Unit), a ROM (Read Only Memory), a RAM (Random Access Memory), an input/output port, etc., and/or various types of circuits, and reads and executes a program that is stored in the storage 19, so as to control an operation of a processing unit 16.

Additionally, such a program may be recorded in a computer-readable storage medium and be installed from such a storage medium into the storage 19 of the control device 4. For a computer-readable storage medium, for example, a hard disk (HD), a flexible disk (FD), a compact disk (CD), a magnetooptical disk (MO), a memory card, etc., are provided.

In the substrate processing system 1 that is configured as described above, first, the substrate transfer device 13 of the carry-in/out station 2 takes a wafer W from a carrier C that is placed in the carrier placing section 11 and places such a taken wafer W on the delivery unit 14. A wafer W that is placed on the delivery unit 14 is taken from the delivery unit 14 and is carried in a processing unit 16, by the substrate transfer device 17 of the processing station 3.

A wafer W that is carried in a processing unit 16 is processed by the processing unit 16, subsequently is carried out of the processing unit 16 by the substrate transfer device 17, and is placed on the delivery unit 14. Then, such a processed wafer W that is placed on the delivery unit 14 is returned to the carrier C of the carrier placing section 11 by the substrate transfer device 13.

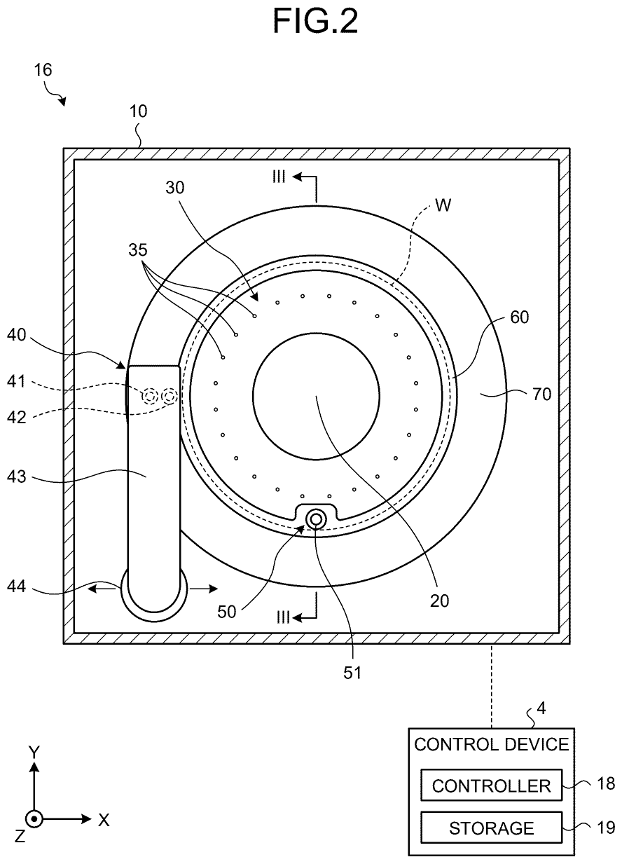

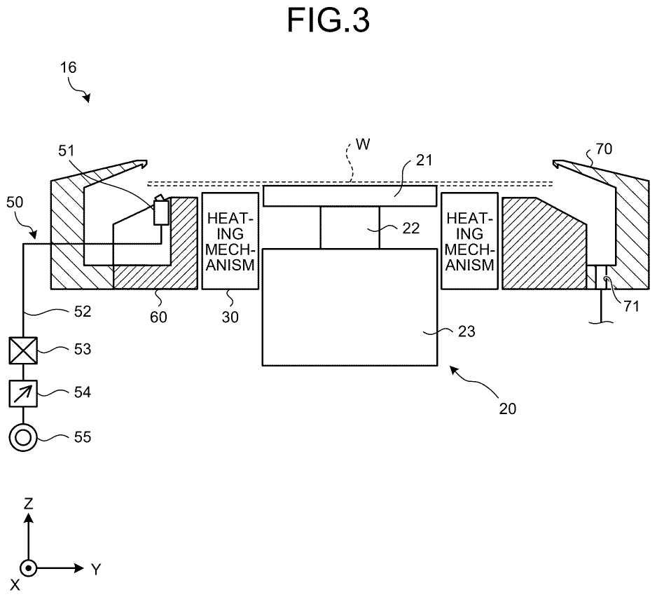

Next, a configuration of a processing unit 16 according to an embodiment will be explained with reference to FIG. 2 and FIG. 3. FIG. 2 is a schematic plan view that illustrates a configuration of a processing unit 16 according to an embodiment. Furthermore, FIG. 3 is a schematic cross-sectional view that illustrates a configuration of a processing unit 16 according to an embodiment. Additionally, FIG. 3 schematically illustrates a cross section in an arrow view along line III-III as illustrated in FIG. 2.

As illustrated in FIG. 2 and FIG. 3, a processing unit 16 according to an embodiment includes a processing container 10, a holding part 20, a heating mechanism 30, a first supply part 40, a second supply part 50, a lower side cup 60, and an outer side cup 70.

The processing container 10 houses the holding part 20, the heating mechanism 30, the first supply part 40, the second supply part 50, the lower side cup 60, and the outer side cup 70.

The holding part 20 holds a wafer W rotatably. Specifically, the holding part 20 includes a vacuum chuck 21, a shaft part 22, and a driving part 23. The vacuum chuck 21 adsorbs and holds a wafer W by vacuuming. The vacuum chuck 21 has a diameter that is less than that of a wafer W, and adsorbs and holds a central part of a back surface of such a wafer W. The shaft part 22 horizontally supports the vacuum chuck 21 at a distal end part thereof. The driving part 23 is connected to a proximal end part of the shaft part 22 and rotates the shaft part 22 around a vertical axis. A wafer W is held horizontally in a state where a front surface thereof is oriented upward with respect to such a holding part 20.

The heating mechanism 30 is arranged at a lower side of a wafer W and an outer side of the holding part 20. Specifically, the heating mechanism 30 is arranged between the holding part 20 and the lower side cup 60.

The heating mechanism 30 supplies a heated fluid to a back surface of a wafer W that is held by the holding part 20, so as to heat such a wafer W. Specifically, the heating mechanism 30 includes a plurality of discharge ports that are arranged side by side in a circumferential direction of a wafer W, and supplies a heated fluid from such a plurality of discharge ports to a back surface of such a wafer W. A heated fluid may be, for example, a heated N₂ gas.

Additionally, in a case where a plan view of a processing unit 16 is provided, a plurality of discharge ports that are possessed by the heating mechanism 30 are positioned at an inner side of a wafer W in a radial direction thereof with respect to a peripheral part of such a wafer W. As an example, a peripheral part of a wafer W is an area with a ring shape and a width of about 1 mm to 3 mm where an end surface of such a wafer W is provided as an outermost circumference thereof. A plurality of discharge ports supply a heated fluid to a back surface of a wafer W at an inner side of such a wafer W in a radial direction thereof with respect to a peripheral part of such a wafer W.

The first supply part 40 supplies a processing liquid to a peripheral part of a wafer W at a side of a front surface thereof. The first supply part 40 includes a chemical liquid nozzle 41 (an example of a first nozzle), a rinse nozzle 42, an arm 43, and a moving mechanism 44. The chemical liquid nozzle 41 and the rinse nozzle 42 are arranged in a state where discharge ports thereof are oriented downward at an upper side of a wafer W.

The chemical liquid nozzle 41 discharges a first processing liquid to a peripheral part of a wafer W at a side of a front surface thereof. A first processing liquid is, for example, a chemical liquid that etches and removes a film that is formed on a front surface of a wafer W. For example, a first processing liquid may be hydrofluoric acid (HF), dilute hydrofluoric acid (DHF), fluoronitric acid, etc. Fluoronitric acid is a mixed liquid of hydrofluoric acid (HF) and nitric acid (HNO₃).

The rinse nozzle 42 discharges a rinse liquid to a peripheral part of a front surface of a wafer W. A rinse liquid is, for example, DIW (deionized water).

Temperatures of a first processing liquid and a rinse liquid are lower than a temperature of a wafer W that is heated by the heating mechanism 30. For example, a temperature of a wafer W that is heated by the heating mechanism 30 is about 100° C. On the other hand, temperatures of a first processing liquid and a rinse liquid are an ordinary temperature (about 20° C. to 25° C.).

The arm 43 extends in a horizontal direction (herein, a direction of a Y-axis) and supports the chemical liquid nozzle 41 and the rinse nozzle 42 at a distal end part thereof. The moving mechanism 44 is connected to a proximal end part of the arm 43 and moves the arm 43 along, for example, a horizontal direction (herein, a direction of an X-axis). Thereby, it is possible to move the chemical liquid nozzle 41 and the rinse nozzle 42 between a processing position at an upper side of a wafer W and a retraction position at an outer side of such a wafer W.

The second supply part 50 supplies a second processing liquid to a peripheral part of a back surface of a wafer W. A second processing liquid may be, for example, a liquid that does not influence a film that is formed on a back surface of a wafer W. “does/do not influence” means that, for example, it/they does/do not dissolve (does/do not contribute to etching of) a film that is formed on a back surface of a wafer W. For such a liquid, it is possible to use, for example, DIW or an organic solvent, etc. Furthermore, a second processing liquid may be a chemical liquid that etches and removes a film that is formed on a back surface of a wafer W. In such a case, a second processing liquid may be a chemical liquid that is identical to a first processing liquid.

A temperature of a second processing liquid is lower than a temperature of a wafer W that is heated by the heating mechanism 30. For example, a temperature of a second processing liquid is an ordinary temperature.

As illustrated in FIG. 3, the second supply part 50 includes a back surface nozzle 51 (an example of a second nozzle), piping 52, a valve 53, a flow rate regulator 54, and a second processing liquid supply source 55. The back surface nozzle 51 is arranged at a lower side of a wafer W and discharges a second processing liquid to a peripheral part of a back surface of such a wafer W.

Additionally, a target liquid landing point for a second processing liquid on a back surface of a wafer W may be an inner side of a front surface of a wafer W in a radial direction thereof with respect to a target liquid landing point for a first processing liquid. As an example, a target liquid landing point for a first processing liquid may be a position of 1 mm inner side of a wafer W in a radial direction thereof from an end surface of such a wafer W. Furthermore, a target liquid landing point for a second processing liquid may be a position of 3 mm inner side of a wafer W in a radial direction thereof from an end surface of such a wafer W.

The second supply part 50 may include a moving mechanism that moves the back surface nozzle 51 in a horizontal direction(s) although illustration thereof is omitted herein. In such a case, it is possible for the second supply part 50 to move the back surface nozzle 51 between a processing position at a lower side of a wafer W and a retraction position at an outer side of such a wafer W.

The piping 52 connects the back surface nozzle 51 and the second processing liquid supply source 55. The valve 53 is provided on a middle part of the piping 52 and opens or closes the piping 52. The flow rate regulator 54 is provided on a middle part of the piping 52 and regulates a flow rate of a second processing liquid that flows through the piping 52. The second processing liquid supply source 55 is, for example, a tank, and stores a second processing liquid therein.

In a case where a second processing liquid is “a liquid that does not influence a film that is formed on a back surface of a wafer W”, such a second processing liquid may be, for example, DIW or an organic solvent. An organic solvent may be, for example, IPA (isopropyl alcohol), etc. Furthermore, in a case where a second processing liquid is a chemical liquid, such a second processing liquid may be, for example, hydrofluoric acid (HF), dilute hydrofluoric acid (DHF), fluoronitric acid, etc.

The lower side cup 60 is a member with a circular ring shape that is arranged at a lower side of a wafer W and an outer side of the heating mechanism 30. The lower side cup 60 is formed of, for example, a member with a high chemical resistance of a fluororesin such as PTFE (polytetrafluoroethylene) and/or PFA (perfluoroalkoxyalkane), etc.

The outer side cup 70 is a member with a ring shape that is provided so as to surround a wafer W and receives a liquid that is scattered from such a wafer W. A drain port 71 is formed on a bottom part of the outer side cup 70. A chemical liquid, etc., that is/are received by the outer side cup 70 is/are stored in a space that is formed by the outer side cup 70 and the lower side cup 60, and subsequently, is/are drained from the drain port 71 to an outside of a processing unit 16.

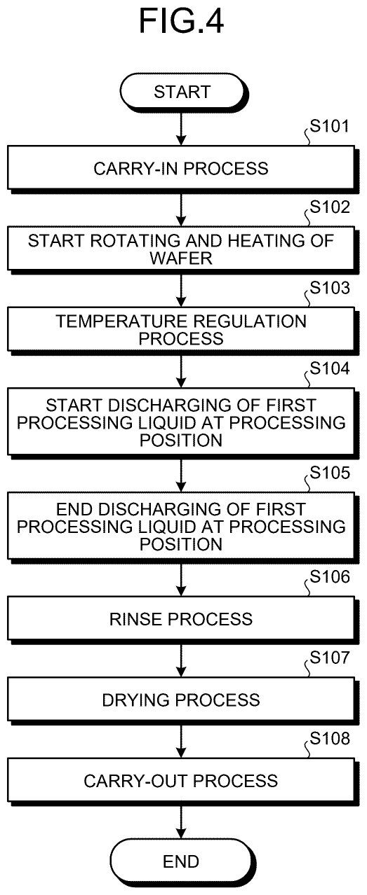

Next, a series of processing procedures that is executed by a processing unit 16 according to an embodiment will be explained with reference to FIG. 4. FIG. 4 is a flowchart that illustrates a series of processing procedures that is executed by a processing unit 16 according to an embodiment. Each processing procedure as illustrated in FIG. 4 is executed according to control that is executed by the controller 18.

As illustrated in FIG. 4, in a processing unit 16, first, a carry-in process is executed (step S101). In a carry-in process, wafer W is carried in a processing container 10 of the processing unit 16 by a substrate transfer device 17 (see FIG. 1). A carried-in wafer W is held by a holding part 20 of the processing unit 16.

Then, the processing unit 16 starts rotating and heating of a wafer W (step S102). A vacuum chuck 21 is rotated by using a driving part 23 of the holding part 20, so that rotating of a wafer W is executed. Heating of a wafer W is executed by using a heating mechanism 30. Rotating of a wafer W is continued until a process at step S106 is ended. Furthermore, heating of a wafer W is continued, at least, until a process at step S104 is ended.

Then, in the processing unit 16, a temperature regulation process is executed (step S103). A temperature regulation process is a process that regulates a temperature of a peripheral part of a wafer W in such a manner that an in-plane temperature distribution of such a wafer W approaches an in-plane temperature distribution during discharging of a first processing liquid from a chemical liquid nozzle 41 that is arranged at a processing position to a peripheral part of such a wafer W that rotates.

Hereinafter, an in-plane temperature distribution during discharging of a first processing liquid from a chemical liquid nozzle 41 that is arranged at a processing position to a peripheral part of a wafer W that rotates will be described as “a distribution during a process”. A processing position for the chemical liquid nozzle 41 is defined by, for example, a horizontal distance from a reference position (a nozzle position “P1” as described later, a so-called home position) for the chemical liquid nozzle 41 at an outer side of a wafer W. A processing position for the chemical liquid nozzle 41 is preset as a position of the chemical liquid nozzle 41 where a first processing liquid lands at a target liquid landing point for such a first processing liquid (for example, a position of 1 mm from an end surface of a wafer W).

In the processing unit 16, while a first processing liquid is discharged from the chemical liquid nozzle 41, the chemical liquid nozzle 41 is introduced (is scanned in) from an outer side of a wafer W to an upper side of such a wafer W, so that a process where the chemical liquid nozzle 41 reaches a processing position as described above is executed. In such a case, a first processing liquid lands on a wafer W before the chemical liquid nozzle 41 reaches a processing position. As a first processing liquid at a temperature that is lower than that of a wafer W lands on a peripheral part of such a wafer W, heat of such a peripheral part of such a wafer W is drawn, so that a temperature difference between such a peripheral part of such a wafer W and its area other than it is caused so as to cause thermal warpage thereof.

A target liquid landing point varies due to thermal warpage. As the chemical liquid nozzle 41 starts to discharge a first processing liquid at a processing position, during developing of thermal warpage, that is, during varying of a target liquid landing point, a position of a first processing liquid that lands on a wafer W actually readily varies between a plurality of wafers W. That is, a variation of a cut width is readily caused between a plurality of wafers W.

Hence, in the processing unit 16 according to an embodiment, a temperature regulation process is executed before a first processing liquid is discharged from the chemical liquid nozzle 41 that is arranged at a processing position to a peripheral part of a wafer W that rotates, so as to complete thermal warpage thereof.

The processing unit 16 according to an embodiment starts discharging of a first processing liquid from the chemical liquid nozzle 41 that is arranged at a processing position to a peripheral part of a wafer W that rotates (step S104) after a temperature regulation process at a step S103 is ended, that is, after thermal warpage thereof is completed.

Thus, a first processing liquid is discharged from the chemical liquid nozzle 41 that is arranged at a processing position to a peripheral part of a wafer W that rotates after thermal warpage thereof is completed, so that, even if such thermal warpage thereof is caused, it is possible to reduce or prevent varying of a cut width that is caused by thermal warpage thereof, between a plurality of wafers W.

The processing unit 16 continues discharging of a first processing liquid at a processing position for a predetermined period of time. Subsequently, the processing unit 16 ends discharging of a first processing liquid (step S105).

Then, in the processing unit 16, a rinse process is executed (step S106). In a rinse process, the processing unit 16 discharges a rinse liquid from the chemical liquid nozzle 41 to a peripheral part of a wafer W at a side of a front surface thereof. Thereby, a first processing liquid that remains on a peripheral part of a wafer W is rinsed away with a rinse liquid.

Then, in the processing unit 16, a drying process is executed (step S107). In a drying process, the processing unit 16 increases a rotational frequency of a wafer W. Thereby, a liquid that remains on a wafer W is shook off by centrifugal force so as to dry such a wafer W.

Then, in the processing unit 16, a carry-out process is executed (step S108). In a carry-out process, a wafer W is carried out of the processing container 10 by the substrate transfer device 17 (see FIG. 1). A wafer W that is carried out of the processing container 10 is subsequently housed in a carrier C by a substrate transfer device 13.

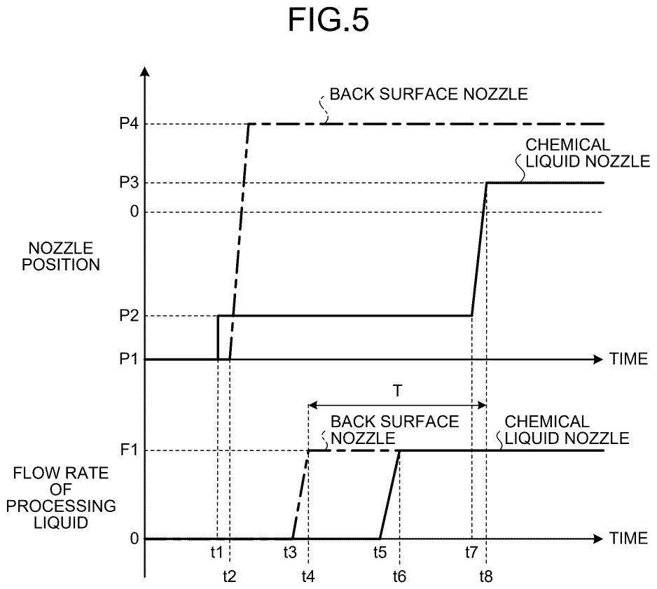

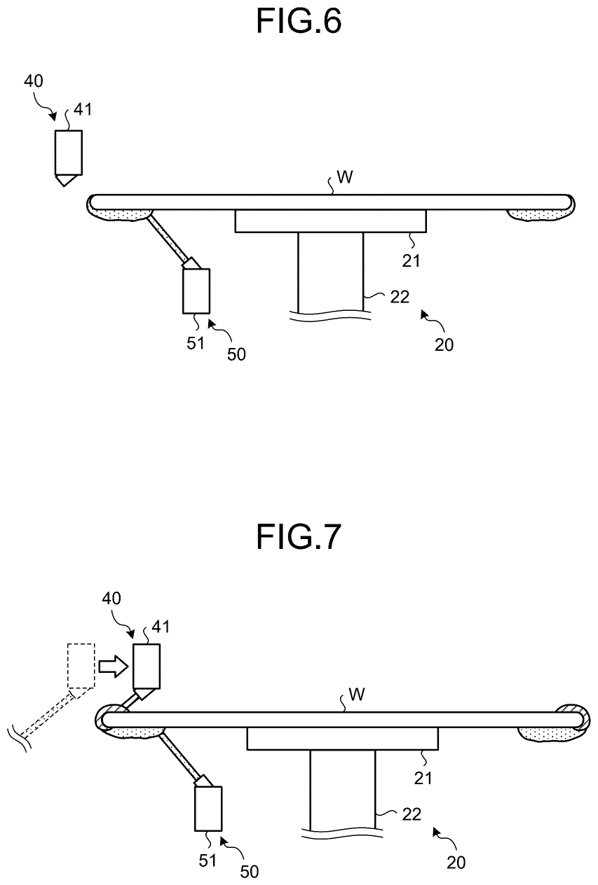

Next, a specific example of a temperature regulation process will be explained. First, an example of a case where a second processing liquid is discharged to a back surface of a wafer W before a first processing liquid is discharged to such a wafer W, so that thermal warpage of such a wafer W is completed, will be explained with reference to FIG. 5 to FIG. 7. FIG. 5 is a timing chart that illustrates an example of an operation of each part in a temperature regulation process according to an embodiment. FIG. 6 and FIG. 7 are diagrams that illustrate an example of an operation of a chemical liquid nozzle 41 and a back surface nozzle 51 in a temperature regulation process according to an embodiment.

FIG. 5 illustrates, in combination, a timing chart where a transverse axis is a time and a longitudinal axis is a nozzle position and a timing chart where a transverse axis is a time and a longitudinal axis is a flow rate of a processing liquid. In FIG. 5, a nozzle position and a flow rate of a processing liquid for the chemical liquid nozzle 41 are indicated by a solid line and a nozzle position and a flow rate of a processing liquid for the back surface nozzle 51 are indicated by a dash-dot line.

Herein, a nozzle position indicates horizontal positions of the chemical liquid nozzle 41 and the back surface nozzle 51. A nozzle position “0” is a position that is predetermined as a position where a processing liquid is discharged to an end surface of a wafer W that is held by a holding part 20. Any of nozzle positions “P1” and “P2” is a position at an outer side of a wafer W. A nozzle position “P1” is a position that is farther away from an end surface of a wafer W than a nozzle position “P2”. A nozzle position “P3” is a processing position for the chemical liquid nozzle 41 and a nozzle position “P4” is a processing position for the back surface nozzle 51. A nozzle position “P4” is positioned at an inner side of a wafer W in a radial direction thereof with respect to a nozzle position “P3”.

As illustrated in FIG. 5, a processing unit 16 first moves the chemical liquid nozzle 41 from a nozzle position P1 to P2 at a time t1. Then, the processing unit 16 moves the back surface nozzle 51 from a nozzle position P1 to a nozzle position P4 that is a processing position at a time t2.

Then, the processing unit 16 starts discharging of a second processing liquid from the back surface nozzle 51 to a peripheral part of a back surface of a wafer W at a time t3 after the back surface nozzle 51 reaches a nozzle position P4. The processing unit 16 increases a flow rate of a discharged second processing liquid from 0 to F1 between a time t3 and a time t4.

Thus, the processing unit 16 discharges a second processing liquid from the back surface nozzle 51 to a peripheral part of a back surface of a wafer W prior to a first processing liquid (see FIG. 6). Thereby, a temperature of a peripheral part of a wafer W is lowered, so as to start to cause thermal warpage thereof. In other words, a temperature distribution of a wafer W starts to approach an in-plane temperature distribution during discharging of a first processing liquid from the chemical liquid nozzle 41 that is arranged at a processing position to a peripheral part of a wafer W that rotates.

Then, the processing unit 16 starts discharging of a first processing liquid from the chemical liquid nozzle 41 at a time t5. Herein, the chemical liquid nozzle 41 is still positioned at a nozzle position P2. Hence, a first processing liquid is discharged to an outer side of a wafer W. The processing unit 16 increases a flow rate of a discharged first processing liquid from 0 to F1 between a time t5 and a time t6.

Then, the processing unit 16 starts moving of the chemical liquid nozzle 41 from a nozzle position P2 to a nozzle position P3 that is a processing position at a time t7. The processing unit 16 moves the chemical liquid nozzle 41 to a nozzle position P3 between a time t7 and a time t8. Thus, the processing unit 16 introduces (scans in) the chemical liquid nozzle 41 from an outer side of a wafer W to an upper side of such a wafer W while a first processing liquid is discharged from the chemical liquid nozzle 41, so that the chemical liquid nozzle 41 reaches a nozzle position P3 that is a processing position.

In the processing unit 16, a period of time from a time t4 to a time t8 (that will be described as a “temperature regulation time period T” below) is preset in such a manner that the chemical liquid nozzle 41 reaches a nozzle position P3 after thermal warpage is completed. A time t4 is a time when the back surface nozzle 51 starts discharging of a second processing liquid at a target flow rate (herein, a flow rate F1) at a processing position. Furthermore, a time to is a time when the chemical liquid nozzle 41 starts discharging of a first processing liquid at a target flow rate (herein, a flow rate F1) at a processing position.

Thus, in the processing unit 16, a scan-in operation of the chemical liquid nozzle 41 is controlled in such a manner that the chemical liquid nozzle 41 reaches a nozzle position P3 that is a processing position, after thermal warpage is completed, that is, after a varying of a target liquid landing point that is caused by thermal warpage is stopped. Thereby, it is possible to reduce or prevent a variation of a cut width between a plurality of wafers W, as compared with a case where the chemical liquid nozzle 41 reaches a processing position during varying of a target liquid landing point.

In the present example, a process that starts discharging of a second processing liquid from the back surface nozzle 51 to a peripheral part of a back surface of a wafer W from a time t4 that is a temperature regulation time period T before a time t8 when the chemical liquid nozzle 41 starts discharging of a first processing liquid at a target flow rate at a processing position is an example of a temperature regulation process.

In the present example, a second processing liquid may be DIW or an organic solvent, etc. A temperature regulation process is executed by using such a second processing liquid, so that it is possible for an in-plane temperature distribution of a wafer W to approach a distribution during a process, without influencing a film that is formed on a back surface of such a wafer W. Additionally, this is not limiting and a second processing liquid may be a chemical liquid that etches and removes a film that is formed on a back surface of a wafer W.

Furthermore, the processing unit 16 continues discharging of a second processing liquid to a peripheral part of a wafer W at a side of a back surface thereof while a first processing liquid is discharged from the chemical liquid nozzle 41 that is arranged at a processing position to a peripheral part of such a wafer W at a side of a front surface thereof. In other words, discharging of a second processing liquid to a peripheral part of a wafer W at a side of a back surface thereof is executed in parallel with discharging of a first processing liquid at a processing position. Thereby, it is possible to reduce or prevent changing of a state of thermal warpage during discharging of a first processing liquid at a processing position, as compared with a case where discharging of a second processing liquid is stopped in middle thereof. Therefore, it is possible to further reduce or prevent varying of a cut width between a plurality of wafers W.

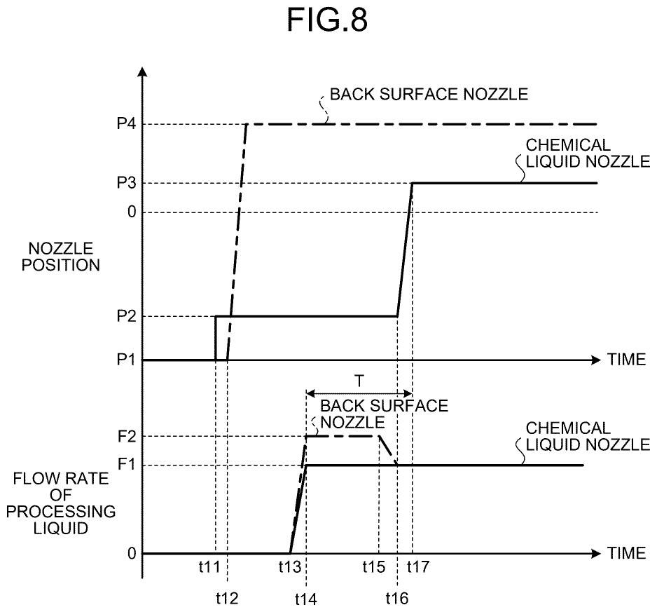

Next, a variation of a temperature regulation process as illustrated in FIG. 5 to FIG. 7 will be explained with reference to FIG. 8. FIG. 8 is a timing chart that illustrates another example of an operation of each part in a temperature regulation process according to an embodiment.

As illustrated in FIG. 8, a processing unit 16 first moves a chemical liquid nozzle 41 from a nozzle position P1 to P2 at a time t11. Then, the processing unit 16 moves a back surface nozzle 51 from a nozzle position P1 to a nozzle position P4 that is a processing position at a time t12.

Then, the processing unit 16 starts discharging of a second processing liquid from the back surface nozzle 51 at a time t13 after the back surface nozzle 51 reaches a nozzle position P4, and starts discharging of a first processing liquid from the chemical liquid nozzle 41.

The processing unit 16 increases a flow rate of a discharged first processing liquid from 0 to F1 between time t13 and a time t14. On the other hand, the processing unit 16 increases a flow rate of a discharged second processing liquid from 0 to F2 (>F1) between a time t13 and a time t14.

The processing unit 16 decreases a flow rate of a discharged second processing liquid from F2 to F1 after discharging of such a second processing liquid at a flow rate F2 is continued from a time t14 to a time t15. The processing unit 16 decreases a flow rate of a discharged second processing liquid from F2 to F1 between a time t15 and a time t16.

Furthermore, the processing unit 16 starts moving of the chemical liquid nozzle 41 from a nozzle position P2 to a nozzle position P3 that is a processing position at a time t16. The processing unit 16 moves the chemical liquid nozzle 41 to a nozzle position P3 between a time t16 and a time t17.

Thus, the processing unit 16 discharges a second processing liquid at a first flow rate (a flow rate F1) in parallel with discharging of a first processing liquid at a processing position. Furthermore, the processing unit 16 discharges a second processing liquid at a second flow rate (a flow rate F2) that is greater than a first flow rate, before discharging of a first processing liquid at a processing position is started. Thus, a second processing liquid is discharged at a high flow rate before discharging of a first processing liquid at a processing position is started, so that it is possible to reduce a period of time until thermal warpage is completed (a temperature regulation time period T). That is, it is possible to reduce a period of time that is needed for a series of processes for a single wafer W.

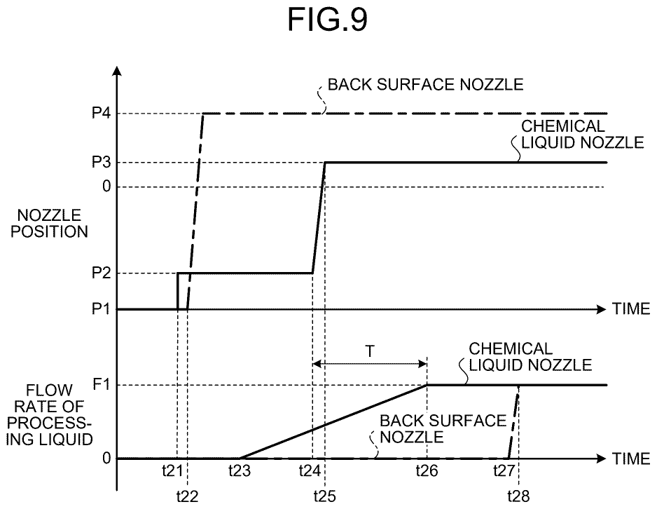

Next, an example of a case where a flow rate of a first processing liquid is gradually increased during moving of a chemical liquid nozzle 41, so that an in-plane temperature distribution of a wafer W approaches a distribution during a process before the chemical liquid nozzle 41 reaches a processing position, will be explained with reference to FIG. 9. FIG. 9 is a timing chart that illustrates another example of an operation of each part in a temperature regulation process according to an embodiment.

As illustrated in FIG. 9, a processing unit 16 first moves a chemical liquid nozzle 41 from a nozzle position P1 to P2 at a time t21. Then, the processing unit 16 moves a back surface nozzle 51 from a nozzle position P1 to a nozzle position P4 that is a processing position at a time t22.

Then, the processing unit 16 starts discharging of a first processing liquid from the chemical liquid nozzle 41 at a time t23 after the back surface nozzle 51 reaches a nozzle position P4. The processing unit 16 increases a flow rate of a discharged first processing liquid from 0 to F1 between a time t23 and a time t26.

The processing unit 16 starts moving of the chemical liquid nozzle 41 from a nozzle position P2 to a nozzle position P3 that is a processing position at a time t24 after a time t23 when discharging of a first processing liquid is started and before a flow rate of a discharged first processing liquid reaches a flow rate F1 that is a target flow rate. The processing unit 16 moves the chemical liquid nozzle 41 to a nozzle position P3 between a time t24 and a time t25. A time t25 is prior to a time t26 when a flow rate of a discharged first processing liquid reaches a target flow rate.

Thus, in the present example, a flow rate of a discharged first processing liquid increases during moving of the chemical liquid nozzle 41. In other words, a flow rate of a discharged first processing liquid increases as the chemical liquid nozzle 41 approaches a processing position. Furthermore, a flow rate of a discharged first processing liquid reaches a target flow rate after it continues to increase even after the chemical liquid nozzle 41 reaches a processing position.

For example, a gas flow that travels from an inner side to an outer side of a wafer W is formed around a peripheral part of a wafer W, by a swirling flow, etc., that is/are caused by rotation of such a wafer W. In a case where a flow rate of a discharged first processing liquid is a low flow rate, a first processing liquid that is discharged from the chemical liquid nozzle 41 readily flows to an outer side of a wafer W due to such a gas flow. Hence, in a case where a flow rate of a discharged first processing liquid is a low flow rate, a liquid landing point for a first processing liquid is shifted to an outer side of a wafer W, as compared with a case where a flow rate of a discharged first processing liquid is a high flow rate.

At a point of time (a time t25) when the chemical liquid nozzle 41 reaches a processing position, a flow rate of a discharged first processing liquid has not yet reached a flow rate F1 that is a target flow rate. Hence, at such a point of time, a first processing liquid lands at an outer side of a wafer W in a radial direction thereof with respect to a target liquid landing point, due to an influence of a gas flow. Subsequently, as a flow rate of a first processing liquid gradually increases, such a first processing liquid is not readily influenced by a gas flow. As a result, a liquid landing point for a first processing liquid gradually approaches a target liquid landing point.

In the present example, a temperature regulation time period T from a time t24 to a time t26 is preset in such a manner that a flow rate of a discharged first processing liquid reaches a flow rate F1 that is a target flow rate after thermal warpage is completed. Thus, a temperature regulation process may be executed by increasing a flow rate of a discharged first processing liquid as the chemical liquid nozzle 41 approaches a processing position. Furthermore, a temperature regulation process may be executed by increasing a flow rate of a discharged first processing liquid in such a manner that a flow rate of a discharged first processing liquid reaches a target flow rate after the chemical liquid nozzle 41 reaches a processing position. A flow rate of a discharged first processing liquid reaches a target flow rate after thermal warpage is completed, that is, after varying of a target liquid landing point that is caused by thermal warpage is stopped, so that it is possible to reduce or prevent a variation of a cut width between a plurality of wafers W.

Additionally, in the present example, the processing unit 16 starts discharging of a second processing liquid at a time t27 after a flow rate of a discharged first processing liquid reaches a flow rate F1 that is a target flow rate. The processing unit 16 increases a flow rate of a discharged second processing liquid from 0 to F1 between a time t27 and a time t28.

Otherwise, a temperature regulation process for the processing unit 16 may be a process that scans-in the chemical liquid nozzle 41 at a comparatively low speed, so that an in-plane temperature distribution of a wafer W approaches a distribution during a process before the chemical liquid nozzle 41 reaches a processing position. For example, a period of time after a first processing liquid lands on a wafer W and before thermal warpage thereof is completed may preliminarily be identified by an experiment, etc., so as to determine a speed of movement of the chemical liquid nozzle 41 based on such an identified period of time. Accordingly, it is possible for a first processing liquid to reach a processing position after thermal warpage is completed, that is, after varying of a target liquid landing point that is caused by thermal warpage is stopped, so that it is possible to reduce or prevent a variation of a cut width between a plurality of wafers W.

### Another/Other Embodiment(s)

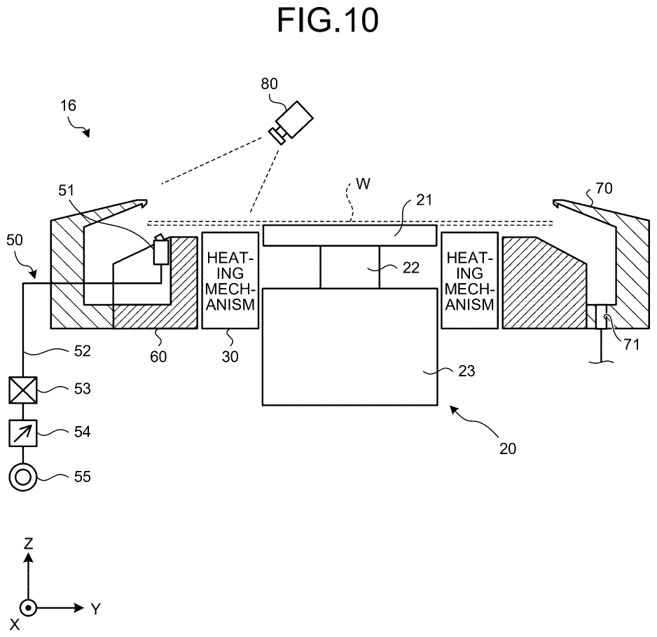

FIG. 10 is a schematic diagram that illustrates a configuration of a processing unit 16 according to another embodiment. As illustrated in FIG. 10, a processing unit 16 may include a warpage detection part 80. The warpage detection part 80 detects a change of an amount of warpage of a wafer W that is held by a holding part 20.

The warpage detection part 80 may be, for example, an image-capturing part that captures an image of a peripheral part of a wafer W. Such an image-capturing part is, for example, a CCD (Charge Coupled Device) camera. An image (an animated image) of a peripheral part of a wafer W where an image thereof is captured by the warpage detection part 80 as an image-capturing part is output to a controller 18.

It is possible for the controller 18 to detect a situation of development of thermal warpage of a wafer W, that is, a change of an amount of warpage of a wafer W, based on an image that is acquired from the warpage detection part 80. Specifically, it is possible for the controller 18 to detect an amount of a change of warpage of a wafer W and a period of time after warpage of such a wafer W starts to change and before a change of such warpage is stopped, based on an image that is acquired from the warpage detection part 80. For example, it is possible to detect an amount of a change of warpage of a wafer W, based on an amount of displacement of an end surface of such a wafer W.

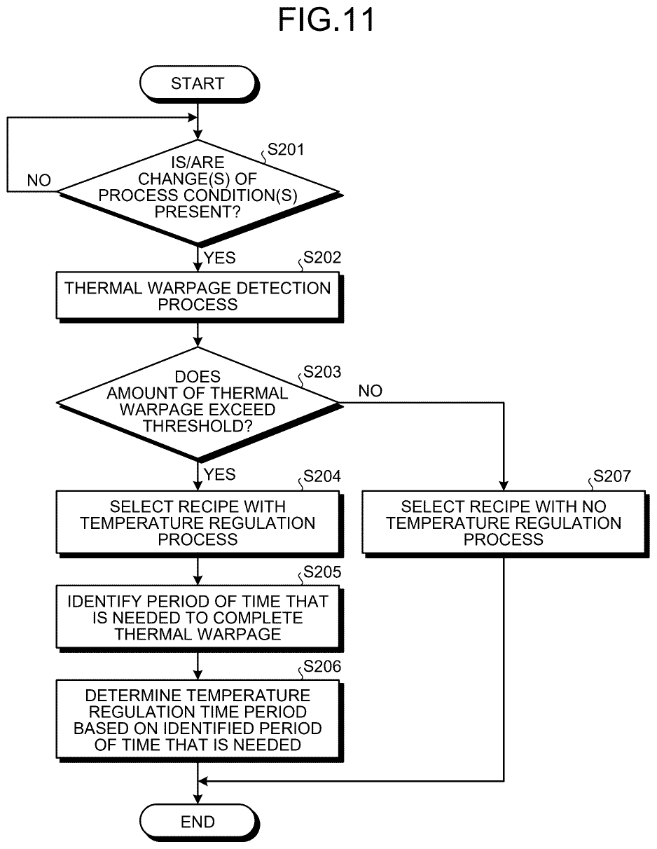

FIG. 11 is a flowchart that illustrates a procedure of a recipe selection process that is executed by a processing unit 16 according to another embodiment.

As illustrated in FIG. 11, a controller 18 determines whether or not a process condition(s) of a series of processes that is executed for a wafer W is changed (step S201). Herein, a process condition(s) is/are, for example, a temperature of heating that is executed by a heating mechanism 30, a flow rate(s) of a processing liquid(s) (a first processing liquid and a second processing liquid), a position(s) of discharging of a processing liquid(s), a liquid type(s) of a processing liquid(s), a type of a substrate, a type of a film, etc. Such a process condition(s) is/are stored as recipe information in a storage 19. The controller 18 may determine that a process condition(s) is/are changed, in a case where a content of recipe information that is stored in the storage 19 is changed.

At step S201, in a case where a process condition(s) is/are not changed (step S201, No), the controller 18 repeats a process at step S201. On the other hand, in a case where it is determined that a process condition(s) is/are changed (step S201, Yes), the controller 18 executes a thermal warpage detection process (step S202).

For example, the controller 18 detects a change of an amount of warpage of a wafer W at a time when a first processing liquid is discharged from a chemical liquid nozzle 41 to, for example, a first wafer W, among a plurality of wafers W (an example of a group of substrates that are process targets) that are housed in a carrier C, by using a warpage detection part 80. Specifically, the warpage detection part 80 acquires, as an image, a situation where a peripheral part of a wafer W is gradually warped by thermal warpage thereof. The controller 18 detects an amount of a change of warpage of a wafer W and a period of time after warpage of such a wafer W starts to change and before a change of such warpage is stopped, based on such an image.

Herein, a process for a first wafer W may be executed based on, for example, a recipe after such a change. However, a temperature regulation process is not executed. Furthermore, “an amount of a change of warpage of a wafer W” is, in other words, an amount of warpage that is caused by thermal warpage that excludes warpage that is possessed by a wafer W before processing thereof.

Then, the controller 18 determines whether or not a detected amount of thermal warpage exceeds a threshold (step S203). In such a process, in a case where it is determined that an amount of thermal warpage exceeds a threshold (step S203, Yes), the controller 18 selects a recipe with a temperature regulation process (step S204). In other words, the controller 18 determines that a temperature regulation process is added to a series of processes for a wafer W.

Then, the controller 18 identifies a period of time that is needed to complete thermal warpage, based on a result of detection at step S202 (step S205).

Then, the controller 18 determines a temperature regulation time period T based on an identified period of time that is needed (step S206). For example, the controller 18 may determine an identified period of time that is needed, as a length of a temperature regulation time period T, or may determine a period of time when a predetermined period of time is added to an identified period of time that is needed, as a length of a temperature regulation time period T. Then, the controller 18 changes recipe information for a process that is executed at step S202 so as to execute a temperature regulation process in a determined temperature regulation time period T.

On the other hand, in a case where an amount of thermal warpage does not exceed a threshold at step S203 (step S203, No), the controller 18 selects a recipe with no temperature regulation process (step S207). That is, the controller 18 does not add a temperature regulation process to a series of processes for a wafer W. In other words, the controller 18 does not change recipe information for a process that is executed at step S202.

As a process at step S206 or step S207 is ended, the controller 18 ends a recipe selection process.

Subsequently, the controller 18 executes a series of processes for a remaining wafer(s) W that is/are housed in a carrier C, according to a determined or selected recipe at step S206 or step S207.

Additionally, the warpage detection part 80 may be other than an image-capturing part. For example, the warpage detection part 80 may be a temperature detection part that detects an in-plane temperature distribution of a wafer W. For such a temperature detection part, it is possible to use, for example, an infrared camera, etc.

In a case where the warpage detection part 80 is a temperature detection part, the controller 18 may determine, for example, whether or not a difference between a temperature of a peripheral part of a wafer W and a temperature of such a wafer W at an inner side of such a peripheral part in a radial direction thereof (for example, a central part of a wafer W) exceeds a threshold, in a determination process at step S203.

As has been described above, a substrate processing apparatus (a processing unit 16 as an example) according to an embodiment includes a holding part (a holding part 20 as an example), a heating mechanism (a heating mechanism 30 as an example), a first nozzle (a chemical liquid nozzle 41 as an example), a second nozzle (a back surface nozzle 51 as an example), a moving mechanism (a moving mechanism 44 as an example), and a controller (a controller 18 as an example). The holding part holds a substrate (a wafer W as an example) horizontally and rotatably. The heating mechanism heats the substrate that is held by the holding part. The first nozzle supplies a first processing liquid to a peripheral part of a front surface of the substrate. The second nozzle supplies a second processing liquid to the peripheral part of a back surface of the substrate. The moving mechanism moves the first nozzle. The controller executes a heating process, a temperature regulation process, and a first discharge process. The heating process heats the substrate that is held by the holding part by using the heating mechanism. The temperature regulation process discharges the second processing liquid from the second nozzle to the peripheral part of the substrate that rotates at a side of a back surface thereof, after the heating process and before the first processing liquid is discharged from the first nozzle that is arranged at a predetermined processing position to the peripheral part of a front surface of the substrate that rotates, in such a manner that an in-plane temperature distribution of the substrate approaches an in-plane temperature distribution in a case where the first processing liquid is discharged from the first nozzle that is arranged at the processing position to the peripheral part of a front surface of the substrate that rotates (a distribution during a process as an example). The first discharge process discharges the first processing liquid from the first nozzle that is arranged at the processing position by using the moving mechanism to the peripheral part of a front surface of the substrate that rotates, after the temperature regulation process.

Therefore, it is possible for a substrate processing apparatus according to an embodiment to reduce or prevent varying of a removal width of a film on a peripheral part of a substrate between substrates that is caused by warpage of such a substrate that is temporarily caused during processing of such a substrate.

It should be considered that an embodiment(s) as disclosed herein is/are not limitative but is/are illustrative in any aspect. In fact, it is possible to implement an embodiment(s) as described above in a variety of modes thereof. Furthermore, an embodiment(s) as described above may be omitted, substituted, and/or modified in various modes thereof without departing from what is claimed as attached and an essence thereof.

### REFERENCE SIGNS LIST

1 substrate processing system
4 control device
16 processing unit
17 substrate transfer device
18 controller
19 storage
20 holding part
21 vacuum chuck
22 shaft part
23 driving part
30 heating mechanism
40 first supply part
41 chemical liquid nozzle
42 rinse nozzle
43 arm
44 moving mechanism
50 second supply part
51 back surface nozzle
80 warpage detection part
W wafer

1. A substrate processing method, comprising:
holding a substrate by using a holding part that holds the substrate horizontally and rotatably;
subsequently heating the substrate that is held thereby;
subsequently regulating a temperature of a peripheral part of the substrate that rotates before a first processing liquid is discharged from a first nozzle that is arranged at a predetermined processing position to the peripheral part, in such a manner that an in-plane temperature distribution of the substrate approaches an in-plane temperature distribution during discharging of the first processing liquid from the first nozzle that is arranged at the processing position to the peripheral part of the substrate that rotates; and
subsequently discharging the first processing liquid from the first nozzle that is arranged at the processing position to the peripheral part of the substrate that rotates.

2. The substrate processing method according to claim 1, wherein:
the discharging the first processing liquid
includes discharging the first processing liquid to the peripheral part of the substrate at a side of a front surface thereof; and
the regulating includes discharging a second processing liquid from a second nozzle to the peripheral part of the substrate that rotates at a side of a back surface thereof.

3. The substrate processing method according to claim 2, further comprising
discharging the second processing liquid from the second nozzle to the peripheral part of the substrate that rotates at a side of a back surface thereof, in parallel with the discharging the first processing liquid.

4. The substrate processing method according to claim 3, wherein:
the discharging the second processing liquid
includes discharging the second processing liquid to the peripheral part of the substrate at a side of a back surface thereof at a first flow rate; and
the regulating includes discharging the second processing liquid to the peripheral part of the substrate at a side of a back surface thereof at a second flow rate that is greater than the first flow rate.

5. The substrate processing method according to claim 2, wherein
the second processing liquid is a liquid that does not influence a film that is formed on a back surface of the substrate.

6. The substrate processing method according to claim 1, wherein:
the discharging the first processing liquid includes moving the first nozzle from an outer side of the substrate to the processing position while the first processing liquid is discharged from the first nozzle; and
the regulating includes increasing a flow rate of the first processing liquid that is discharged therefrom as the first nozzle approaches the processing position.

7. The substrate processing method according to claim 1, further comprising
determining whether or not the regulating is executed for the substrate in a case where a processing condition is changed.

8. The substrate processing method according to claim 7, further comprising
detecting a change of warpage of the substrate at a time when the first processing liquid is discharged from the first nozzle to one substrate among a group of substrates that are processing targets, wherein
the determining includes determining whether or not the regulating is executed for a substrate that is processed after the one substrate among the group of substrates that are the processing targets, based on a result of detection in the detecting.

9. A substrate processing apparatus, comprising:
a holding part that holds a substrate horizontally and rotatably;
a heating mechanism that heats the substrate that is held by the holding part;
a first nozzle that supplies a first processing liquid to a peripheral part of a front surface of the substrate;
a second nozzle that supplies a second processing liquid to the peripheral part of a back surface of the substrate;
a moving mechanism that moves the first nozzle; and
a controller, wherein
the controller is configured to execute:
a heating process that heats the substrate that is held by the holding part by using the heating mechanism;
a temperature regulation process that discharges the second processing liquid from the second nozzle to the peripheral part of the substrate that rotates at a side of a back surface thereof, after the heating process and before the first processing liquid is discharged from the first nozzle that is arranged at a predetermined processing position to the peripheral part of a front surface of the substrate that rotates, in such a manner that an in-plane temperature distribution of the substrate approaches an in-plane temperature distribution in a case where the first processing liquid is discharged from the first nozzle that is arranged at the processing position to the peripheral part of a front surface of the substrate that rotates; and
a first discharge process that discharges the first processing liquid from the first nozzle that is arranged at the processing position by using the moving mechanism to the peripheral part of a front surface of the substrate that rotates, after the temperature regulation process.

10. The substrate processing apparatus according to claim 9, wherein
the controller is configured to execute a second discharge process that discharges the second processing liquid from the second nozzle to the peripheral part of the substrate that rotates at a side of a back surface thereof, in parallel with the first discharge process.

11. The substrate processing apparatus according to claim 10, wherein
the controller is configured to discharge the second processing liquid from the second nozzle to the peripheral part of the substrate at a side of a back surface thereof at a first flow rate, in the second discharge process, and discharge the second processing liquid from the second nozzle to the peripheral part of the substrate at a side of a back surface thereof at a second flow rate that is greater than the first flow rate, in the temperature regulation process.

12. The substrate processing apparatus according to claim 9, wherein
the controller is configured to move the first nozzle from an outer side of the substrate to the processing position while the first processing liquid is discharged from the first nozzle, in the first discharge process, and increase a flow rate of the first processing liquid that is discharged therefrom as the first nozzle approaches the processing position, in the temperature regulation process.

13. The substrate processing apparatus according to claim 9, further comprising
a warpage detection part that detects a change of warpage of the substrate that is held by the holding part, wherein
the controller is configured to execute:
a detection process that detects a change of warpage of the substrate at a time when the first processing liquid is discharged from the first nozzle to one substrate among a group of substrates that are processing targets, by using the warpage detection part; and
a determination process that determines whether or not the temperature regulation process is executed for a substrate that is processed after the one substrate among the group of substrates that are the processing targets, based on a result of detection in the detection process.

14. The substrate processing apparatus according to claim 13, wherein
the warpage detection part is an image-capturing part that captures an image of the peripheral part of the substrate.

15. The substrate processing apparatus according to claim 13, wherein
the warpage detection part is a temperature detection part that detects an in-plane temperature distribution of the substrate.
